(19) United States
(12) Patent Application Publication
(10) Pub. No.: US 2026/0191046 A1
(43) Pub. Date: Jul. 2, 2026

(54) GLASS CORE THROUGH GLASS VIA WITH PROFILE TO REDUCE STRESS INDUCED CRACKING

(71) Applicant: Intel Corporation, Santa Clara, CA (US)

(72) Inventors: Gene T. CORYELL, II, Maricopa, AZ (US); Srinivas Venkata Ramanuja PIETAMBARAM, Chandler, AZ (US); Hanyu SONG, Chandler, AZ (US); Ahmed BARAKAT, Phoenix, AZ (US); Deniz TURAN, Chandler, AZ (US); Vishal Bhimrao ZADE, Chandler, AZ (US)

(21) Appl. No.: 19/003,661

(22) Filed: Dec. 27, 2024

(51) Int. Cl. H01L 23/498; H01L 23/15

(52) U.S. Cl. CPC H10W 70/635; H10W 70/692

(57) ABSTRACT

Embodiments disclosed herein include an apparatus that includes a substrate with a first surface and a second surface opposite from the first surface. In an embodiment, the substrate comprises a glass layer and a via is provided through the substrate. In an embodiment, the via comprises a first portion with a first sidewall that is oriented at a first angle with respect to the first surface of the substrate, and the first portion of the via is at the first surface of the substrate. In an embodiment, a second portion of the via includes a second sidewall that is oriented at a second angle with respect to the first surface of the substrate, and the second angle is different than the first angle.

### BACKGROUND

Glass cores for package substrates are an attractive option due to the increased stiffness, planarity, and routing density that they provide compared to existing organic cores. However, the brittle nature of glass provides several challenges with respect to manufacturing. One issue that is present for glass cores is the high stress that is generated during the formation of vias through the glass core (i.e., through glass vias (TGVs)). With traditional plating, a seed layer is provided along the sidewalls of the via opening, and the via is plated out from the sidewalls. The different coefficients of thermal expansion (CTE) between the glass core and the via can induce significant stress into the glass core. In many instances, the stress is ultimately dissipated by the glass core cracking. A cracked glass core has significant reliability concerns, and leads to poor yield during the manufacture of package substrates.

### BRIEF DESCRIPTION OF THE DRAWINGS

FIG. 1 is a cross-sectional illustration of a glass core with a through glass via (TGV) that passes through a thickness of the glass core, in accordance with an embodiment.

FIG. 2A is a cross-sectional illustration of a glass core with a TGV that comprises a goblet shaped cross-section, in accordance with an embodiment.

FIG. 2B is a zoomed in cross-sectional illustration of a portion of a TGV in a glass core that illustrates an upper portion of the TGV, in accordance with an embodiment.

FIG. 2C is a zoomed in cross-sectional illustration of a portion of a TGV in a glass core that illustrates an upper portion of the TGV, in accordance with an additional embodiment.

FIG. 2D is a zoomed in cross-sectional illustration of a portion of a TGV in a glass core that illustrates an upper portion of the TGV, in accordance with an additional embodiment.

FIG. 2E is a cross-sectional illustration of a glass core with a TGV that comprises a liner between the TGV and the glass core, in accordance with an embodiment.

FIG. 2F is a cross-sectional illustration of a glass core with a TGV that includes a goblet cross-sectional shape at a single end of the TGV, in accordance with an embodiment.

FIGS. 3A-3F are cross-sectional illustrations depicting a process for forming a TGV in a glass core, where the TGV has a goblet shaped cross-section, in accordance with an embodiment.

FIG. 4 is a flow diagram of a process for forming a TGV in a glass core, in accordance with an embodiment.

FIG. 5 is a cross-sectional illustration of an electronic system that comprises a package substrate with a glass core that includes a TGV with a goblet shaped cross-section, in accordance with an embodiment.

FIG. 6 is a schematic of a computing device built in accordance with an embodiment.

### EMBODIMENTS OF THE PRESENT DISCLOSURE

Described herein are glass substrates with through glass vias (TGVs) that comprise a goblet shaped cross-section, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, existing glass cores provide improved stiffness, planarity, and routing density compared to organic cores. However, the coefficient of thermal expansion (CTE) differences between the metallic material of vias (e.g., through glass vias (TGVs)) and the glass substrate can result in the generation of stresses in the glass core during plating and/or during thermal cycling. Particularly, the stresses between the metallic material of the TGV and the glass core may result in cracking of the glass core at the ‘shoulder’ where the TGV sidewall transitions from a non-vertical entrant angle to a vertical angle.

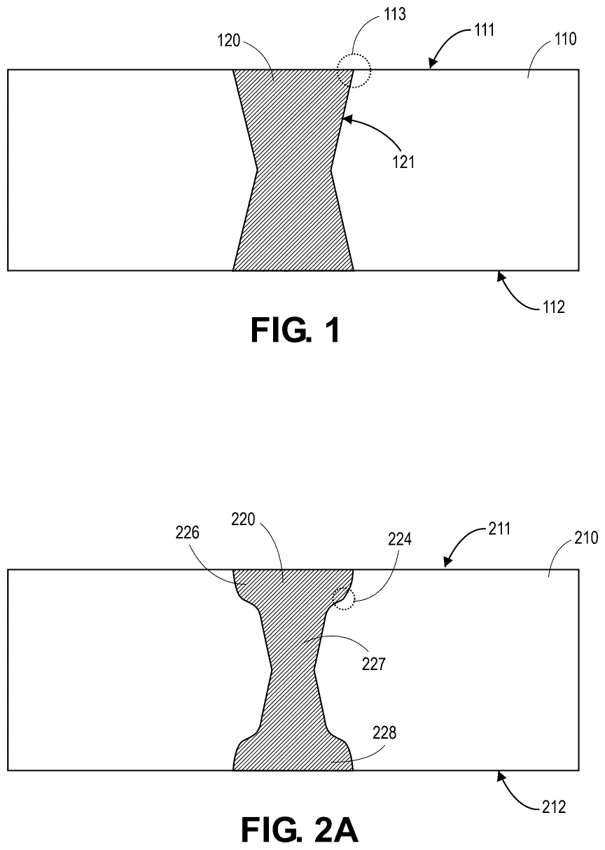

For example, FIG. 1 is a cross-sectional illustration of such TGV 120 in a glass core 110. As shown, the TGV 120 passes through the glass core 110 from a first surface 111 to a second surface 112 that is opposite from the first surface 111. The shoulder 113 may be a point of weakness where the sidewall 121 of the TGV 120 reaches the top surface 111 of the glass core 110 at a steep angle. Due to the concentration of stress at this point during plating and/or during thermal cycling, cracking at the shoulder 113 can be a common occurrence. This reduces yield of the manufacturing process and can result in reliability issues throughout the life of the package substrate that is fabricated on the glass core 110.

Accordingly, embodiments disclosed herein may include the fabrication of TGVs that have a recessed shoulder. Moving the junction where stresses are deeper into the bulk of the glass core allows for the glass core to withstand higher stresses. As such, the glass core is less likely to fracture or crack during plating and/or during thermal cycling. This allows for higher yields and improved reliability. In an embodiment, the resulting TGV may sometimes be referred to herein as having a goblet shaped cross-section. That is, the top and/or bottom of the TGV may have a width that is wider than a width of a middle portion of the TGV. Further, the sidewalls of the wider portions and the sidewall of the narrower middle portion may have different slopes relative to the top or bottom surface of the glass core in some embodiments. Stated differently, a TGV with a goblet shaped cross-section may have a stem portion (i.e., the middle portion) and a cup portion (i.e., the upper (and/or lower) portion).

The goblet shaped cross-section may be fabricated with a dual laser process. In an embodiment, a first laser process is used to form a narrow channel through the glass core. The first laser process may also result in the formation of a heat-affected zone along the edges of the narrow channel. Thereafter, a second laser process is used to remove a portion of the glass core to form recesses at the top and/or bottom surfaces of the glass core. These recesses have widths that are larger than the width of the narrow channel. The second laser process may use a different type of laser than the first laser process. For example, the first laser process may use a Bessel laser, and the second laser process may use a femtosecond laser or an excimer laser. After the recesses are formed, an etching process may be used to expand the opening to the desired size of the TGV. A plating process may then be used to plate the TGV within the opening. A liner (e.g., a buffer layer) may also be provided between the TGV and the glass core in some embodiments.

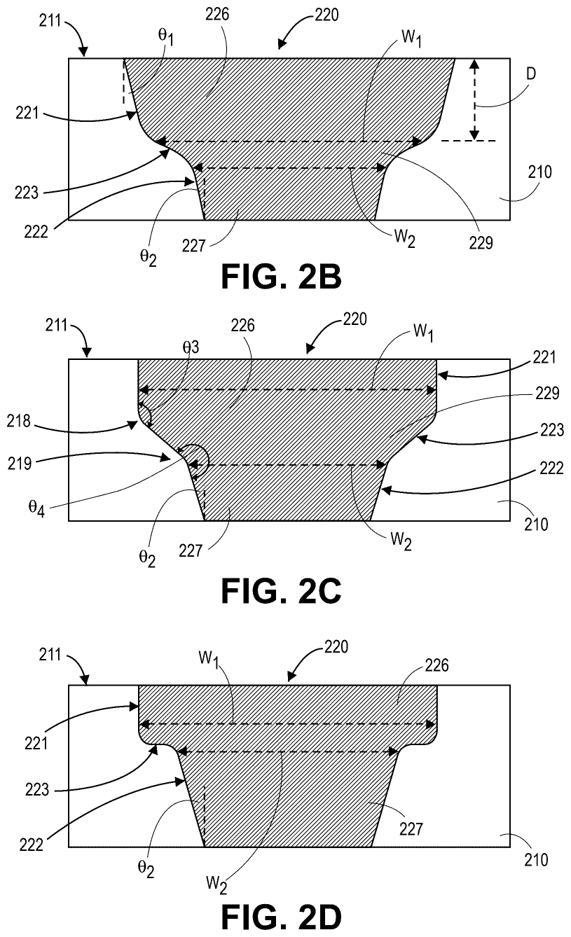

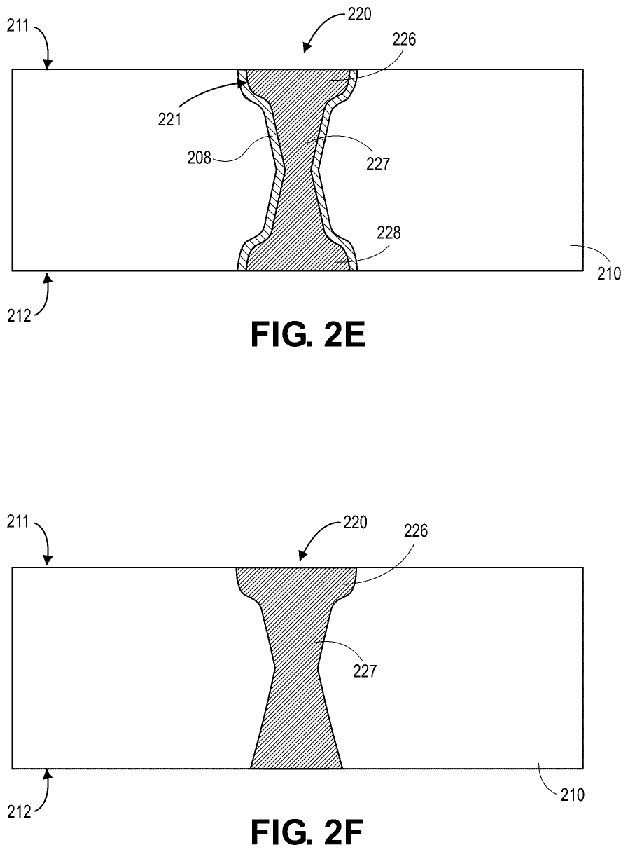

Referring now to FIG. 2A, a cross-sectional illustration of a glass core 210 with a TGV 220 is shown, in accordance with an embodiment. In an embodiment, the glass core 210 may include a top surface 211 and a bottom surface 212 that is opposite from the top surface 211. As shown, the TGV 220 may have a goblet shaped cross-section. For example, a first portion 226 proximate to the top surface 211 may be wider than a second portion 227 to form a goblet shape. Similarly, a third region 228 proximate to the bottom surface 212 may be wider than the second portion 227.

As indicated by the dashed circle, a corner region 224 is recessed down within the depth of the glass core 210. Recessing the corner region 224 allows for the stress to be induced into a stronger portion of the glass core 210 as opposed to being on the exposed top surface 211 (as shown in FIG. 1). This allows for improvements to the manufacturing yield and the reliability of the glass core 210.

In an embodiment, a via opening for the TGV 220 that passes through the thickness of the glass core 210 may be formed with any suitable process. For example, a laser assisted etching process may be used to form the via opening in some embodiments. Particularly, a first laser process and a second laser process may be used, as will be described in greater detail herein. In an embodiment, the TGV 220 may be a high aspect ratio TGV 220. For example, an aspect ratio (height: diameter) of the TGV 220 may be 5:1 or greater, 10:1 or greater, or 20:1 or greater. Though, embodiments may also be used with smaller aspect ratio TGVs 220 as well.

In an embodiment, the glass core 210 may be substantially all glass. The glass core 210 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, glass core 210 may be distinguished from, for example, the “prepreg” or “FR4” core of a Printed Circuit Board (PCB) substrate which typically comprises glass fibers embedded in a resinous organic material, such as an epoxy.

The glass core 210 may have any suitable dimensions. In a particular embodiment, the glass core 210 may have a thickness that is approximately 50 μm or greater. For example, the thickness of the glass core 210 may be between approximately 50 μm and approximately 1.4 mm. Though, smaller or larger thicknesses may also be used. The glass core 210 may have edge dimensions (e.g., length, width, etc.) that are approximately 10 mm or greater. For example, edge dimensions may be between approximately 10 mm to approximately 600 mm. Though, larger or smaller edge dimensions may also be used. More generally, the area dimensions of the glass core 210 (from an overhead plan view) may be between approximately 10 mm×10 mm and approximately 600 mm×600 mm. In an embodiment, the glass core 210 may have a first side that is perpendicular or orthogonal to a second side. In a more general embodiment, the glass core 210 may comprise a rectangular prism volume with sections (e.g., vias) removed and filled with other materials (e.g., metal, etc.).

The glass core 210 may comprise a single monolithic layer of glass. In other embodiments, the glass core 210 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the glass core 210 may each have a thickness less than approximately 50 μm. For example, discrete layers of glass in the glass core 210 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The glass core 210 may be any suitable glass formulation that has the necessary mechanical robustness and compatibility with semiconductor packaging manufacturing and assembly processes. For example, the glass core 210 may comprise aluminosilicate glass, borosilicate glass, alumino-borosilicate glass, silica, fused silica, or the like. In some embodiments, the glass core 210 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the glass core 210 may comprise silicon and oxygen, as well as any one or more of aluminum, boron, magnesium, calcium, barium, tin, sodium, potassium, strontium, phosphorus, zirconium, lithium, titanium, or zinc. In an embodiment, the glass core 210 may comprise at least 23 percent silicon (by weight) and at least 26 percent oxygen (by weight). In some embodiments, the glass core 210 may further comprise at least 5 percent aluminum (by weight).

It is to be appreciated that the specific shape of the cross-section of the TGV may be variable depending on the particular processing conditions that are used to form the opening through the glass core. Several different examples of some cross-sectional shapes of the TGV are shown with respect to FIGS. 2B-2D.

Referring now to FIG. 2B, a cross-sectional illustration of part of a TGV 220 (i.e., the upper end of the TGV 220) is shown, in accordance with an embodiment. While the TGV 220 is a substantially monolithic structure, the TGV 220 may be described as having different portions. For example, a first portion 226 may be at the top of the TGV 220 adjacent to the top surface 211 of the glass core 210. A second portion 227 may be below the first portion 226, and an intermediate portion 229 may be between the first portion 226 and the second portion 227.

In an embodiment, the first portion 226 may have a first sidewall 221. The first sidewall 221 may be oriented with the top surface 211 at a first angle θ₁ away from the normal (dashed line) of the top surface 211. The first angle θ₁ may be within 15° of the normal, within 25° of the normal, or within 45° of the normal. In an embodiment, the second portion 227 may have a second sidewall 222. The second sidewall 222 may be oriented with the top surface 211 at an second angle θ₂ away from the normal (dashed line) of the top surface 211. The second angle θ₂ may be different than the first angle θ₁. In an embodiment, the first sidewall 221 may extend into a depth D of the substrate 220 that is at least 10 μm.

In an embodiment, a width of the first portion 226 may be different than a width of the second portion 227. More particularly, a minimum width W₁ of the first portion 226 may be wider than a maximum width W₂ of the second portion 227. That is, the first portion 226 and the second portion 227 may have non-uniform widths through their thicknesses. In an embodiment, a third sidewall 223 of the intermediate portion 229 may connect the first sidewall 221 to the second sidewall 222 to provide a continuous edge for the TGV 220.

Referring now to FIG. 2C, a cross-sectional illustration of a portion of a TGV 220 in a glass core 210 is shown, in accordance with an additional embodiment. The TGV 220 in FIG. 2C is similar to the TGV 220 in FIG. 2B, with the exception of the slopes of the first sidewall 221 and the third sidewall 223. For example, the first sidewall 221 is approximately normal to the top surface 211 of the glass core 210. The second surface may still have an angle θ₂ that is different than the angle of the first sidewall 221 relative to the top surface 211.

As shown in FIG. 2C, a first corner 218 may be provided at the junction between the first sidewall 221 and the third sidewall 223, and a second corner 219 may be provided at the junction between the third sidewall 223 and the second sidewall 222. In an embodiment, the first corner 218 may define an obtuse third angle θ₃ between the first sidewall 221 and the third sidewall 223, and the second corner 219 may define a reflex fourth angle θ₄ between the third sidewall 223 and the second sidewall 222. In an embodiment, the first corner 218 and the second corner 219 may be rounded. The rounded profile of the corners may be the result of the etching process (e.g., a wet etching process) that is used to define the opening through the glass core 210 in which the TGV 220 is formed. In an embodiment, a width W₁ of the first portion 226 may be wider than a maximum width W₂ of the second portion 227.

Referring now to FIG. 2D, a cross-sectional illustration of a portion of a TGV 220 in a glass core 210 is shown, in accordance with an additional embodiment. The TGV 220 in FIG. 2D is similar to the TGV 220 in FIG. 2C, with the exception of the orientation of the third sidewall 223 relative to the top surface 211 of the glass core 210. For example, the third sidewall 223 may be substantially parallel to the top surface 211 of the glass core 210. In such an embodiment, the TGV 220 may not have a discernable intermediary portion 229 since the third sidewall 223 stays at substantially the same depth within the glass core 210 along an entire length of the third sidewall 223. That is, the first portion 226 may be in direct contact with the second portion 227.

Referring now to FIG. 2E, a cross-sectional illustration of a glass core 210 with a TGV 220 between the top surface 211 and the bottom surface 212 of the glass core 210 is shown, in accordance with an embodiment. In an embodiment, the TGV 220 in FIG. 2E may be similar to the TGV 220 in FIG. 2A, with the addition of a liner 208 between the sidewall 221 of the TGV 220 and the glass core 210. In an embodiment, the liner 208 may be used to provide an additional buffer layer that absorbs stress that would otherwise be induced into the glass core 210. In an embodiment, the liner 208 may comprise a polymeric material or other low modulus material. For example, the liner 208 may comprise parylene or the like.

Referring now to FIG. 2F, a cross-sectional illustration of a glass core 210 with a TGV 220 is shown, in accordance with an additional embodiment. In an embodiment, the TGV 220 may comprise a first end (i.e., the top end in FIG. 2F) that is different than a second end (i.e., the bottom end in FIG. 2F). For example, the first end may include a first portion 226 that has the goblet shaped cross-section and the second end may be a continuation of the second portion 227. In such an embodiment, the second laser process (described in greater detail below) may only be implemented on the top portion of the glass core 210.

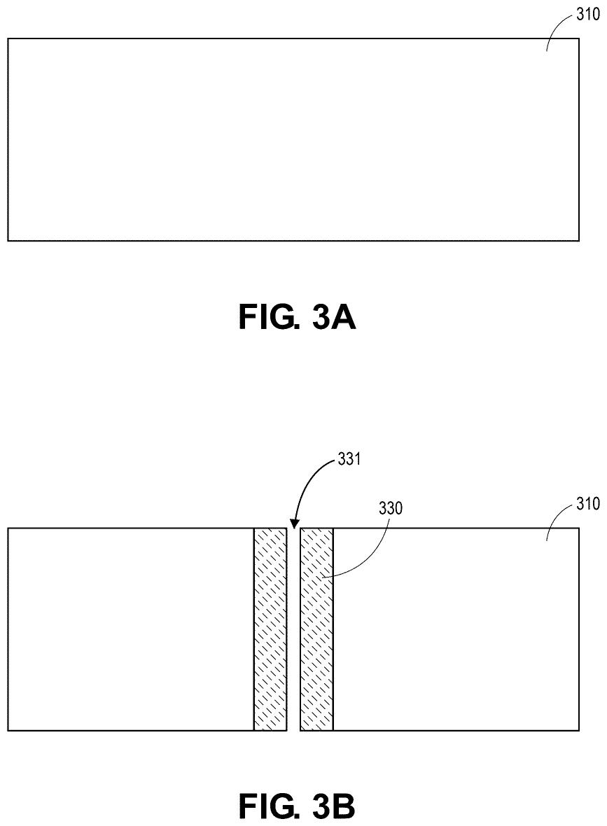

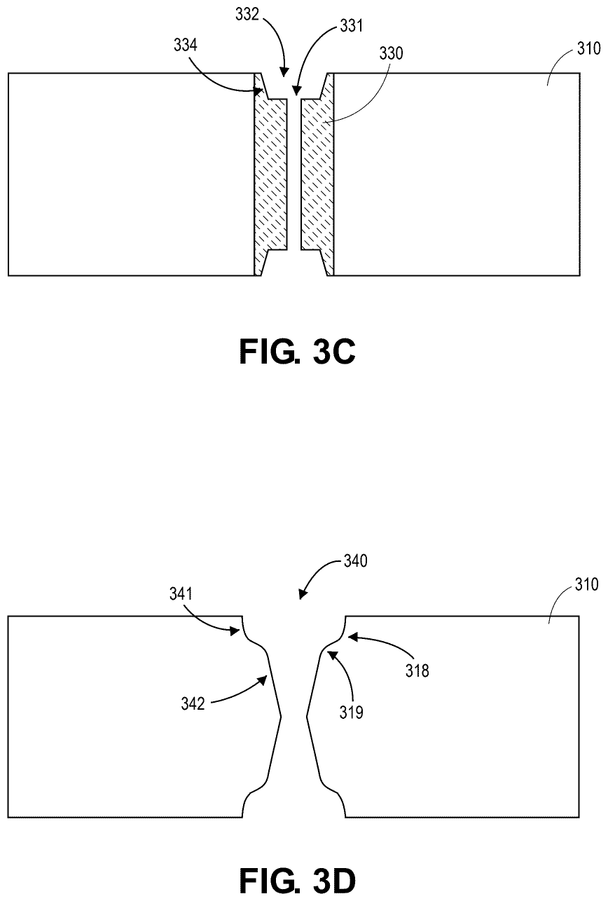

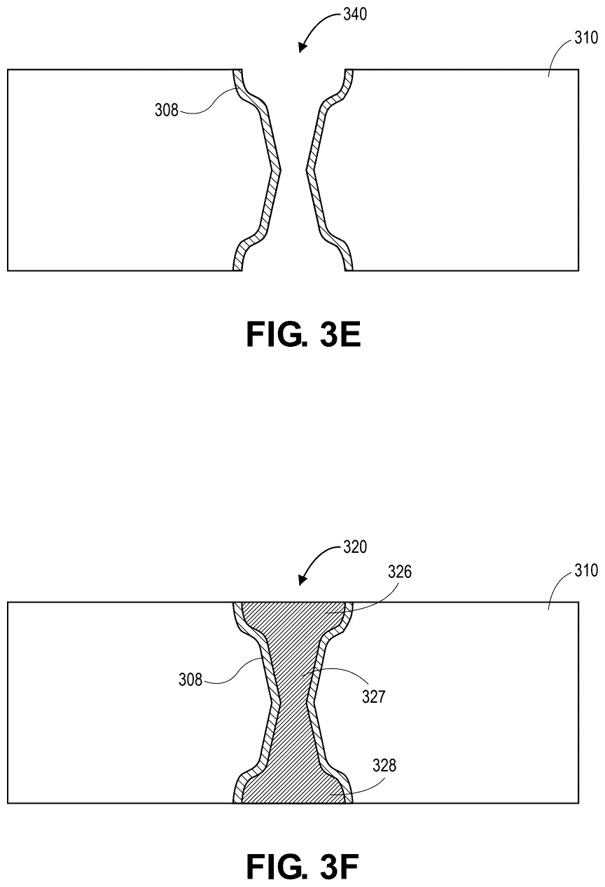

Referring now to FIGS. 3A-3F , a series of cross-sectional illustrations depicting a process for forming a glass core 310 with a TGV 320 with a goblet shaped cross-section is shown, in accordance with an embodiment. In an embodiment, the TGV 320 may be similar to any of the TGVs described in greater detail herein.

Referring now to FIG. 3A, a cross-sectional illustration of a glass core 310 is shown, in accordance with an embodiment. In an embodiment, the glass core 310 may be similar to any of the glass cores described in greater detail herein.

Referring now to FIG. 3B, a cross-sectional illustration of the glass core 310 after a first laser process is used to pattern the glass core 310 is shown, in accordance with an embodiment. In an embodiment, the first laser process may include exposing the glass core to a first type of laser. For example, the first type of laser may include a Bessel laser. The first laser process may result in the formation of an opening 331 through a thickness of the glass core 310. Additionally, a heat-affected zone 330 may be provided along the sides of the opening 331.

Referring now to FIG. 3C, a cross-sectional illustration of the glass core 310 after a second laser process is used to form recesses 332 into the top and bottom surfaces of the glass core 310. The recesses 332 may intersect the opening 331. The recesses 332 may be provided within the heat-affected zone 330 in some embodiments. In an embodiment, the recesses 332 may have sidewalls 334. The sidewalls 334 may have a slope, or the sidewalls 334 may be substantially vertical. In an embodiment, the recesses 332 are wider than a width of the opening 331.

The second laser process may include a laser ablation process that is used to ablate portions of the glass core 310. For example, the second laser process may use a femtosecond laser or an excimer laser. The femtosecond laser may have a wavelength between 200 nm and 1,000 nm in some embodiments. For example, a wavelength of 530 nm may be used in some instances. Though, any suitable wavelength may be used in other embodiments.

Referring now to FIG. 3D, a cross-sectional illustration of the glass core 310 after an etching process is used to complete the formation of an opening 340 through a thickness of the glass core 310 is shown, in accordance with an embodiment. In an embodiment, the etching process may include a wet etching process. In a particular embodiment, the etching process may include a high-temperature NaOH etching chemistry. Particularly, the heat-affected zone 330 may be preferentially etched by the etching chemistry. The etching process may result in a widening of the opening 331 and/or the recesses 332. The resulting opening 340 may include corner regions 318 and 319 that provide a goblet shaped cross-section for the opening. For example, sidewall 341 may be provided at an upper end and a lower end of the opening 340, and sidewall 342 may be provided between the sidewalls 341. The slope of the sidewalls 341 may be different than a slop of the sidewall 342. In an embodiment, the closest corner region to the surface of the glass core 310 (e.g., corner region 318) may be at least 10 μm away from the top surface of the glass core 310, at least 20 μm away from the top surface of the glass core 310, or at least 40 μm away from the top surface of the glass core 310.

Referring now to FIG. 3E, a cross-sectional illustration of the glass core 310 after a liner 308 is applied along surfaces of the opening 340 is shown, in accordance with an embodiment. In an embodiment, the liner 308 may include a low modulus material, such as a polymer or the like. For example, the liner 308 may comprise parylene or the like. While the liner 308 is shown as only being along the sidewalls of the opening 340, it is to be appreciated that the liner 308 may also be deposited over the top surface and the bottom surface of the glass core 310.

Referring now to FIG. 3F, a cross-sectional illustration of the glass core 310 after a TGV 320 is formed in the opening 340 is shown, in accordance with an embodiment. In an embodiment, the TGV 320 may be formed with a plating process. For example, a seed layer (not shown) may be deposited on the liner 308, and the bulk of the TGV 320 may be plated up from the seed layer. In an embodiment, the TGV 320 may be similar to any of the TGVs described in greater detail herein. For example, the TGV 320 may comprise a first portion 326, a second portion 327, and a third portion 328. The first portion 326 and the third portion 328 may be wider than the second portion 327 in order to provide a goblet shaped cross-section.

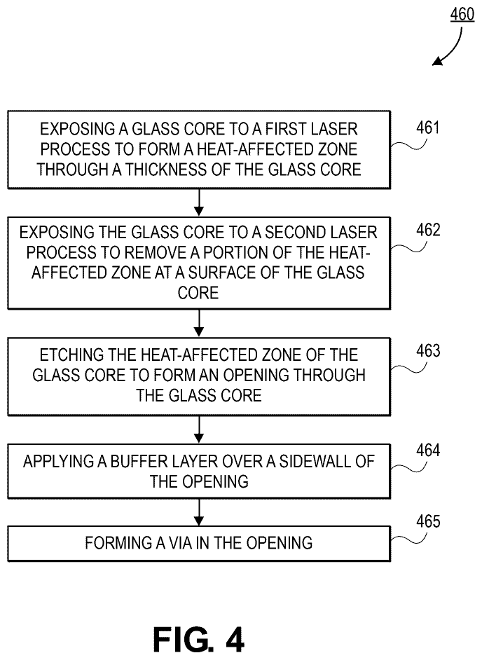

Referring now to FIG. 4, a flow diagram depicting a process 460 for forming a glass core with a TGV that includes a goblet shaped cross-section is shown, in accordance with an embodiment. In an embodiment, the process for forming the TGV in the glass core may be similar to the process described in greater detail above with respect to FIGS. 3A-3F.

In an embodiment, the process 460 may begin with operation 461, which comprises exposing a glass core to a first laser process to form a heat-affected zone through a thickness of the glass core. In an embodiment, the first laser process may include the use of a Bessel laser or the like. In some embodiments, a channel or hole may also be formed through a thickness of the glass core during the first laser process.

In an embodiment, the process 460 may continue with operation 462, which comprises exposing the glass core to a second laser process to remove a portion of the heat-affected zone at a surface of the glass core. The removal of the portion of the heat-affected zone may result in the formation of a recess at the surface of the glass core. In an embodiment, the recess may be wider than a hole or channel formed with the first laser process. In an embodiment, the second laser process may use a femtosecond laser or an excimer laser. For example, a wavelength of the femtosecond laser may be between 200 nm and 1,000 nm. In a particular embodiment, the wavelength may be 530 nm.

In an embodiment, the process 460 may continue with operation 463, which comprises etching the heat-affected zone of the glass core to form an opening through the glass core. In an embodiment, the opening comprises a goblet shaped cross-section. For example, the portion of the opening where the recess was may be wider than a lower portion of the opening. The etching process may include a wet etching process. For example, a high temperature NaOH etching chemistry may be used to etch the glass core to form the opening.

In an embodiment, the process 460 may continue with operation 464, which comprises applying a buffer layer over a sidewall of the opening. In an embodiment, the buffer layer may be similar to any of the liners described in greater detail herein. For example, the buffer layer may comprise a low modulus material, such as a polymer. In a particular embodiment, the buffer layer may comprise parylene or the like.

In an embodiment, the process 460 may continue with operation 465, which comprises forming a via in the opening. In an embodiment, the via may be formed with a plating process. For example, a seed layer may be deposited over the buffer layer, and an electrochemical plating process may be used to plate up the via in the opening. In an embodiment, the via may be similar to any of the TGVs described in greater detail herein. For example, the via may comprise a goblet shaped cross-section.

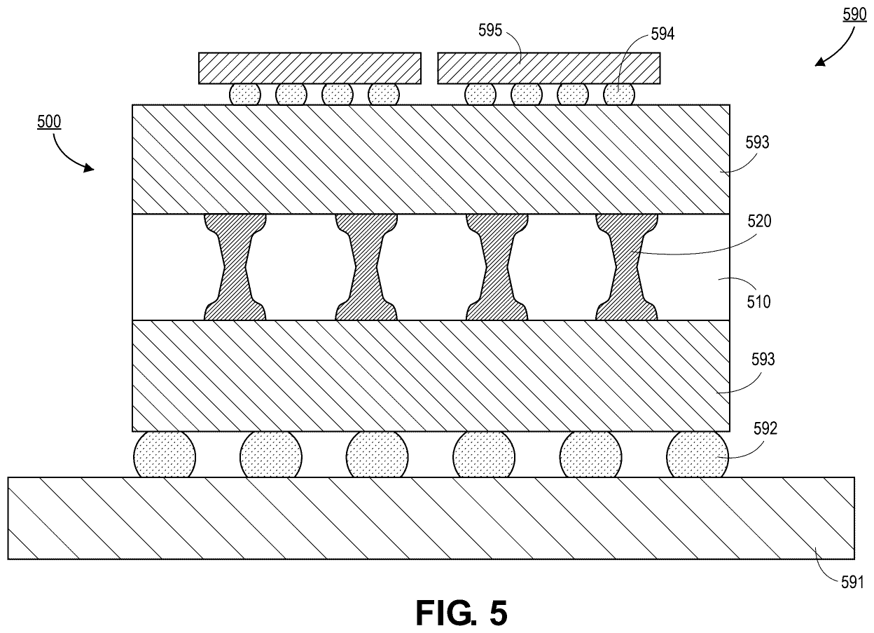

Referring now to FIG. 5, a cross-sectional illustration of an electronic system 590 is shown, in accordance with an embodiment. In an embodiment, the electronic system 590 may comprise a board 591, such as a printed circuit board (PCB), a motherboard, or the like. In an embodiment, the board 591 may be coupled to a package substrate 500 by second level interconnects (SLIs) 592. In an embodiment, the SLIs 592 may comprise solder balls, sockets, or the like.

In an embodiment, the package substrate 500 may comprise a glass core 510 with TGVs 520. The glass core 510 and the TGVs 520 may be similar to any of the glass cores and/or TGVs described in greater detail herein. For example, the TGVs 520 may comprise a goblet shaped cross-section. That is, upper portions and/or lower portions of the TGVs 520 may be wider than middle portions of the TGVs 520. In an embodiment, the particular slopes, angles, and/or shapes of any of the sidewalls of the TGVs 520 may be similar to any of those described in greater detail herein. While not shown in FIG. 5, the TGVs 520 may be separated from the glass core 510 by a low modulus liner, such as parylene or the like.

In an embodiment, the package substrate 500 may also comprise buildup layers 593 that are provided over and under the glass core 510. The buildup layer 593 may include electrical routing (not shown) to electrically couple the TGVs 520 to the SLIs 592 and first level interconnects (FLIs) 594.

In an embodiment, one or more dies 595 may be coupled to the buildup layer 593 by the FLIs 594. The FLIs 594 may be any suitable FLI architecture, such as solder balls, copper bumps, hybrid bonding interfaces, or the like. In an embodiment, the one or more dies 595 may be any type of die (e.g., a processor die (e.g., a central processing unit (CPU), a graphics processing unit (GPU), an XPU), a memory die, a communications die, a power management die, and/or the like). In an embodiment, two or more dies 595 may be electrically coupled together by a bridge (not shown) that is embedded in the buildup layer 593 or provided over the buildup layer 593.

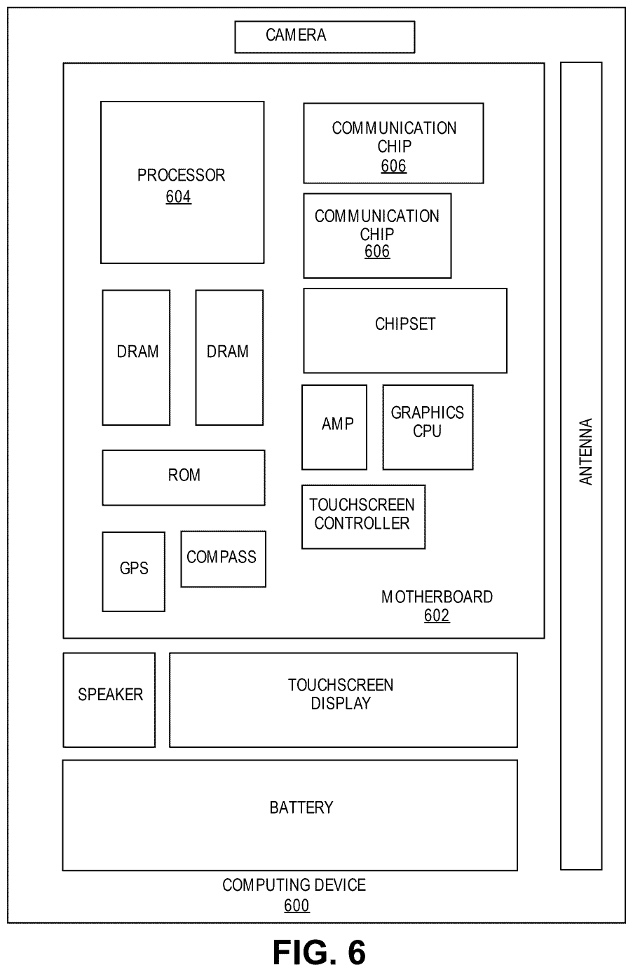

FIG. 6 illustrates a computing device 600 in accordance with one implementation of the disclosure. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604. In an embodiment, a device package is coupled to the board 602. One or both of the processor 604 or the communication chip 606 may be coupled to the board 602 through the device package.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the disclosure, the integrated circuit die of the processor may be part of a package substrate with a glass core that comprises TGVs that include a goblet shaped cross-section that are formed with a dual laser process, in accordance with embodiments described herein. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the disclosure, the integrated circuit die of the communication chip may be part of a package substrate with a glass core that comprises TGVs that include a goblet shaped cross-section that are formed with a dual laser process, in accordance with embodiments described herein.

In an embodiment, the computing device 600 may be part of any apparatus. For example, the computing device may be part of a personal computer, a server, a mobile device, a tablet, an automobile, or the like. That is, the computing device 600 is not limited to being used for any particular type of system, and the computing device 600 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

### EXAMPLES

Example 1: an apparatus, comprising: a substrate with a first surface and a second surface opposite from the first surface, wherein the substrate comprises a glass layer; and a via through the substrate, wherein the via comprises: a first portion with a first sidewall that is oriented at a first angle with respect to the first surface of the substrate, and wherein the first portion of the via is at the first surface of the substrate; and a second portion with a second sidewall that is oriented at a second angle with respect to the first surface of the substrate, wherein the second angle is different than the first angle, and wherein the first portion and the second portion are provided on a same side of a midline between the first surface and the second surface of the substrate.

Example 2: the apparatus of Example 1, wherein a narrowest width of the first portion is greater than a widest width of the second portion.

Example 3: the apparatus of Example 1 or Example 2, wherein the first sidewall is coupled to the second sidewall by a third sidewall, and wherein the third sidewall is oriented at a third angle with respect to the first surface of the substrate that is different than the first angle and the second angle.

Example 4: the apparatus of Example 3, wherein the third sidewall is substantially parallel to the first surface of the substrate.

Example 5: the apparatus of Example 3 or Example 4, wherein a first corner between the first sidewall and the third sidewall and a second corner between the third sidewall and the second sidewall are both rounded.

Example 6: the apparatus of Examples 1-5, wherein the first angle of the first sidewall results in the first sidewall being within 15° of being orthogonal to the first surface of the substrate.

Example 7: the apparatus of Examples 1-6, wherein the first portion of the via has a thickness of 10 μm or more.

Example 8: the apparatus of Examples 1-7, further comprising: a liner between the via and the substrate.

Example 9: the apparatus of Examples 1-8, further comprising: a dielectric buildup layer over the substrate; and a die over the dielectric buildup layer, and wherein the die is electrically coupled to the via.

Example 10: the apparatus of Examples 1-9, wherein the via further comprises: a third portion with a third sidewall that is oriented at the first angle with respect to the first surface of the substrate, and wherein the third portion of the via is at the second surface of the substrate.

Example 11: an apparatus, comprising: a substrate, wherein the substrate comprises a glass layer; and a via through a thickness of the substrate, wherein the via comprises: a first corner between a first sidewall of the via and a second sidewall of the via; and a second corner between the second sidewall of the via and a third sidewall of the via.

Example 12: the apparatus of Example 11, wherein the first corner and the second corner are rounded.

Example 13: the apparatus of Example 11 or Example 12, wherein the first corner defines an obtuse angle between the first sidewall and the second sidewall, and wherein the second corner defines a reflex angle between the second sidewall and the third sidewall.

Example 14: the apparatus of Examples 11-13, wherein the first corner defines an angle between the first sidewall and the second sidewall that is non-orthogonal.

Example 15: the apparatus of Examples 11-14, wherein the first sidewall extends into the substrate to a depth of at least 10 μm.

Example 16: the apparatus of Examples 11-15, further comprising: a liner between the via and the substrate.

Example 17: the apparatus of Examples 11-16, wherein the substrate is a core of a package substrate.

Example 18: an apparatus, comprising: a glass core; a via through a thickness of the glass core, wherein the via comprises a goblet shaped cross-section; dielectric buildup layers over and under the glass core; a die electrically coupled to the via through electrical routing within the dielectric buildup layers; and a board coupled to the dielectric buildup layers.

Example 19: the apparatus of Example 18, further comprising: a liner between the glass core and the via.

Example 20: the apparatus of Example 18 or Example 19, wherein a corner of a sidewall of the via closest to a top surface of the glass core is at least 10 μm away from the top surface of the glass core.

What is claimed is:

1. An apparatus, comprising:
a substrate with a first surface and a second surface opposite from the first surface, wherein the substrate comprises a glass layer; and
a via through the substrate, wherein the via comprises:
a first portion with a first sidewall that is oriented at a first angle with respect to the first surface of the substrate, and wherein the first portion of the via is at the first surface of the substrate; and
a second portion with a second sidewall that is oriented at a second angle with respect to the first surface of the substrate, wherein the second angle is different than the first angle, and wherein the first portion and the second portion are provided on a same side of a midline between the first surface and the second surface of the substrate.

2. The apparatus of claim 1, wherein a narrowest width of the first portion is greater than a widest width of the second portion.

3. The apparatus of claim 1, wherein the first sidewall is coupled to the second sidewall by a third sidewall, and wherein the third sidewall is oriented at a third angle with respect to the first surface of the substrate that is different than the first angle and the second angle.

4. The apparatus of claim 3, wherein the third sidewall is substantially parallel to the first surface of the substrate.

5. The apparatus of claim 3, wherein a first corner between the first sidewall and the third sidewall and a second corner between the third sidewall and the second sidewall are both rounded.

6. The apparatus of claim 1, wherein the first angle of the first sidewall results in the first sidewall being within 15° of being orthogonal to the first surface of the substrate.

7. The apparatus of claim 1, wherein the first portion of the via has a thickness of 10 μm or more.

8. The apparatus of claim 1, further comprising:
a liner between the via and the substrate.

9. The apparatus of claim 1, further comprising:
a dielectric buildup layer over the substrate; and
a die over the dielectric buildup layer, and wherein the die is electrically coupled to the via.

10. The apparatus of claim 1, wherein the via further comprises:
a third portion with a third sidewall that is oriented at the first angle with respect to the first surface of the substrate, and wherein the third portion of the via is at the second surface of the substrate.

11. An apparatus, comprising:
a substrate, wherein the substrate comprises a glass layer; and
a via through a thickness of the substrate, wherein the via comprises:
a first corner between a first sidewall of the via and a second sidewall of the via; and
a second corner between the second sidewall of the via and a third sidewall of the via.

12. The apparatus of claim 11, wherein the first corner and the second corner are rounded.

13. The apparatus of claim 11, wherein the first corner defines an obtuse angle between the first sidewall and the second sidewall, and wherein the second corner defines a reflex angle between the second sidewall and the third sidewall.

14. The apparatus of claim 11, wherein the first corner defines an angle between the first sidewall and the second sidewall that is non-orthogonal.

15. The apparatus of claim 11, wherein the first sidewall extends into the substrate to a depth of at least 10 μm.

16. The apparatus of claim 11, further comprising:
a liner between the via and the substrate.

17. The apparatus of claim 11, wherein the substrate is a core of a package substrate.

18. An apparatus, comprising:
a glass core;
a via through a thickness of the glass core, wherein the via comprises a goblet shaped cross-section;
dielectric buildup layers over and under the glass core;
a die electrically coupled to the via through electrical routing within the dielectric buildup layers; and
a board coupled to the dielectric buildup layers.

19. The apparatus of claim 18, further comprising:
a liner between the glass core and the via.

20. The apparatus of claim 18, wherein a corner of a sidewall of the via closest to a top surface of the glass core is at least 10 μm away from the top surface of the glass core.
